(19) United States
(12) Patent Application Publication
(10) Pub. No.: US 2026/0276450 A1
(43) Pub. Date: Sep. 17, 2026

(54) LIGHT DETECTION ELEMENT

(71) Applicant: TDK Corporation, Tokyo (JP)

(72) Inventors: Takekazu YAMANE, Tokyo (JP); Takeshi NOJIRI, Tokyo (JP); Tetsuya SHIBATA, Tokyo (JP); Tomohito MIZUNO, Tokyo (JP); Hideaki FUKUZAWA, Tokyo (JP)

(73) Assignee: TDK Corporation, Tokyo (JP)

(21) Appl. No.: 19/564,529

(22) Filed: Mar. 12, 2026

(30) Foreign Application Priority Data
Mar. 14, 2025 (JP) 2025-041749

(51) Int. Cl. G01J 5/0806; G01J 5/10; H04B 10/40

(52) U.S. Cl. CPC G01J 5/0806; G01J 5/10; H04B 10/40

(57) ABSTRACT

A light detection element includes a magnetic element having a first ferromagnetic layer, a second ferromagnetic layer, and a spacer layer sandwiched between the first and second ferromagnetic layers, and a main lens 21 and at least one sub-lens 22 that focus incident light to the magnetic element. The main lens and the sub-lens are metalenses 25 including a plurality of nanostructures 26. The planar size of the multiple nanostructures in the main lens decreases as the distance from the optical center of the main lens increases in each region determined according to the distance from the optical center of the main lens, and the planar size of the multiple nanostructures in the sub-lens decreases as the distance from the optical center of the sub-lens increases in each region determined according to the distance from the optical center of the sub-lens.

### CROSS-REFERENCE TO RELATED APPLICATION

This application claims a priority, under the Paris Convention, to Japanese Patent Application No. 2025-041749 filed on Mar. 14, 2025, the entirety of which is incorporated herein by reference.

### TECHNICAL FIELD

The present disclosure relates to a light detection element.

### BACKGROUND

Photoelectric conversion elements such as light detection elements are used in various applications. For example, Japanese Patent Application Publication No. 2001-292107 describes a receiver device that receives optical signals using a photodiode. The photodiode is, for example, a pn junction diode using a semiconductor pn junction, and converts light into an electrical signal. For example, U.S. Pat. No. 9,842,874 describes an optical sensor using a semiconductor pn junction and an image sensor using this optical sensor.

Furthermore, for example, Japanese Patent Application Publication No. 2022-69387 discloses an optical sensor using a magnetic element and a receiver device using this optical sensor, and Japanese Patent Application Publication No. 2023-110453 discloses a technology that combines an optical sensor using a magnetic element with a metalens.

As recognized by the present inventors, light detection elements using semiconductor pn junctions are widely used, but new light detection elements are required for further development. In addition, when the light detection element is very small and the spot of the irradiated light is large, there is a concern that the light irradiated to the light detection element will be irradiated to areas other than the light detection element, causing heat generation in those areas, thereby resulting in slowing down the heat dissipation from the light detection element and deteriorating the high-speed response. Therefore, it is necessary to concentrate the light in a narrow area of the light detection element to reduce the spot of light irradiated to the light detection element.

### SUMMARY

One aspect of the present disclosure provides the light detection element that comprises a magnetic element including a first ferromagnetic layer, a second ferromagnetic layer, and a spacer layer sandwiched between the first ferromagnetic layer and the second ferromagnetic layer, a main lens including a metalens having a plurality of nanostructures arranged two-dimensionally, which irradiates incident light onto the magnetic element, and at least one sub-lens including a metalens having a plurality of nanostructures arranged two-dimensionally, which focuses the incident light to the magnetic element, wherein the size of the plurality of nanostructures in the main lens as viewed in a plan view from the optical axis direction of the main lens decreases as the distance from the optical center of the main lens increases in each region defined by the discontinuity points of equation (1) as boundaries, and the size of the plurality of nanostructures in the sub-lens as viewed in a plan view from the optical axis direction of the sub-lens decreases as the distance from the optical center of the sub-lens increases in each region defined by the discontinuity points of equation (2) as boundaries.

$$ϕ ( r ) = - 2 π ( \frac{\sqrt{{f}^{2} + {r}^{2}} - f}{λ} - floor ( \frac{\sqrt{{f}^{2} + {r}^{2}} - f}{λ} ) ) \qquad ( 1 )$$

$$ϕ ( r ) = - 2 π ( \frac{\sqrt{{f}^{2} + {( r - a )}^{2}} - f}{λ} - floor ( \frac{\sqrt{{f}^{2} + {( r - a )}^{2}} - f}{λ} ) ) + Δ ϕ \qquad ( 2 )$$

(In the above equations (1) and (2), r is the distance from the optical center of the main lens, f is the focal length of the main lens and the sub-lens, λ is the wavelength of the incident light, φ is the phase, a is the distance between the optical center of the main lens and the optical center of the sub-lens, Δφ is the phase difference, and floor is the floor function.)

### BRIEF DESCRIPTION OF DRAWINGS

FIG. 1 shows a diagram showing the configuration of a light detection element according to a first embodiment of the present disclosure.

FIG. 2 shows a partially enlarged cross-sectional view showing the configuration of the magnetic element shown in FIG. 1.

FIG. 3 shows a diagram showing how light is focused by a lens in the light detection element shown in FIG. 1.

FIG. 4 shows a perspective view showing the configuration of the pillars that make up the metalens.

FIG. 5 shows a graph showing the relationship between the diameter of the pillars and the phase of light passing through the pillars.

FIG. 6 shows a plan view showing the results of a simulation of the configuration of the metalens in FIG. 1.

FIG. 7 shows a partially enlarged plan view showing the boundaries, regions, etc. of the simulation results in FIG. 6.

FIG. 8A shows a graph showing the results of a simulation of the relationship between the position of the pillars in the metalens in FIG. 6 and the phase of light passing through the pillars.

FIG. 8B shows a graph showing the results of a simulation of the relationship between the position of the pillars and the diameter of the pillars.

FIG. 9A shows a plan view showing the simulation results of the light spot (intensity distribution) on the focal plane for the light detection element of FIG. 1.

FIG. 9B shows a graph showing the simulation results.

FIG. 10 shows a plan view showing the lens configuration of a light detection element according to a second embodiment of the present disclosure.

FIG. 11 shows a plan view showing the lens configuration of a light detection element according to a third embodiment of the present disclosure.

FIG. 12 shows a diagram showing the configuration of a light detection element according to related art.

FIG. 13 shows a diagram showing how light is focused by a lens in the light detection element shown in FIG. 12.

FIG. 14 shows a plan view showing the simulation results of the metalens configuration of FIG. 12.

FIG. 15A shows a graph showing the relationship between the position of the pillars in the metalens of FIG. 12 and the phase of the light passing through the pillars.

FIG. 15B shows a graph showing the relationship between the position of the pillars and the pillar diameter.

FIG. 16A shows a plan view showing the simulation results of the light spot (intensity distribution) on the focal plane for the light detection element according to the related art of FIG. 12.

FIG. 16B shows a graph showing the simulation results.

### DETAILED DESCRIPTION

According to the present disclosure, the irradiated light is concentrated in a narrow area to reduce the spot of light irradiated on the light detection element, and thus the heat energy generated by the light can be efficiently dissipated, thereby providing a light detection element capable of high-speed light detection.

Hereinafter, the embodiments of the present disclosure will be described in detail with reference to the drawings.

Here, it should be noted that for ease of understanding, the scale of each part in the drawings may differ from the actual scale. In the xyz Cartesian coordinate system set in the drawings, the x-axis direction and the y-axis direction are horizontal, and the z-axis direction is vertical. The positive direction of the z-axis is also called the upward direction, and the negative direction of the z-axis is also called the downward direction, but this has nothing to do with the direction of gravity. In the directions such as parallel, right angle, orthogonal, horizontal, vertical, up and down, left and right, a deviation that does not impair the effect of the embodiments is allowed. In addition, a symbol “~” indicating a numerical range means that the numerical values written before and after it are included as the lower and upper limits.

First, the first embodiment of the present disclosure will be described herein after.

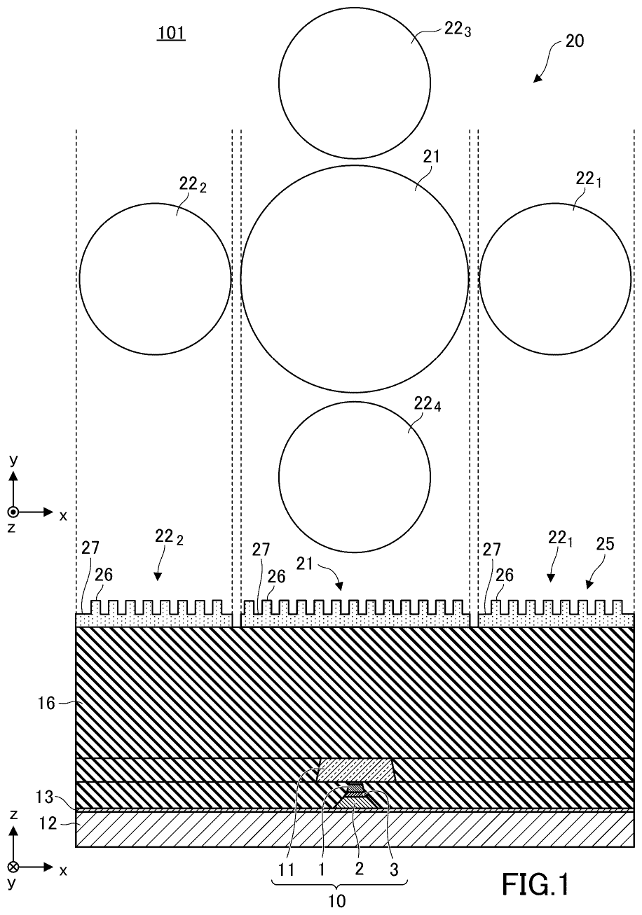

The lower diagram in FIG. 1 is a cross-sectional view showing the configuration of a light detection element 101 according to the first embodiment of the present disclosure, and the upper diagram is a plan view showing the schematic configuration of the lens system of the light detection element 101. As shown in FIG. 1, the light detection element 101 includes a main lens 21, four sub-lenses 22₁, 22₂, 22₃, and 22₄, and a magnetic element 10. The four sub-lenses 22₁, 22₂, 22₃, and 22₄, are, for example, arranged in close proximity to the periphery of the main lens 21 at equal intervals. Hereinafter, any one of the sub-lenses 22₁, 22₂, 22₃, and 22₄, or the whole of them will be referred to as the “sub-lens 22,” and the main lens 21 and/or the sub-lens 22 will be referred to as the “lens 20.” The light detection element 101 may be columnar, for example, rectangular or cylindrical.

The light that passes through the lens 20 is irradiated onto the magnetic element 10. The magnetic element 10 detects the irradiated light and converts it into an electrical signal. This electrical signal is extracted using a first electrode 11 and a second electrode 12 provided above and below the magnetic element 10.

The “light” described in this specification is not limited to the visible light, but may be the infrared light, which has a longer wavelength than the visible light, or the ultraviolet light, which has a shorter wavelength than the visible light. The wavelength of the visible light is, for example, 380 nm or more and less than 800 nm. The wavelength of the infrared light is, for example, 800 nm or more and less than 1 mm. The wavelength of the ultraviolet light is, for example, 200 nm or more and less than 380 nm.

Each component is described below.

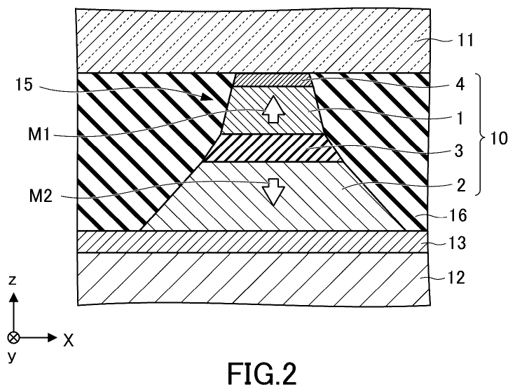

FIG. 2 is a partially enlarged cross-sectional view showing the configuration of the magnetic element 10 of FIG. 1. As shown in FIG. 2, the magnetic element 10 includes at least a first ferromagnetic layer 1, a second ferromagnetic layer 2, and a spacer layer 3 sandwiched between the first ferromagnetic layer 1 and the second ferromagnetic layer 2. In FIG. 2, the second ferromagnetic layer 2, the spacer layer 3, the first ferromagnetic layer 1, and the cap layer 4 are stacked in this order in the positive direction of the z-axis to form a laminate 15. The laminate 15 constituting the magnetic element 10 may further include other layers such as a third ferromagnetic layer, a buffer layer, a seed layer, a magnetic coupling layer, and a perpendicular magnetization induction layer if necessary.

As shown in FIGS. 1 and 2, a first electrode 11 is formed on the lens 20 side of the laminate 15, and a second electrode 12 is formed on the opposite side of the laminate 15 to the lens 20 via a cap layer 13. The magnetic element 10 may include the first electrode 11, the second electrode 12, the cap layer 13, the insulating layer 16, etc., in addition to the laminate 15. The cap layer 4 is located between the first ferromagnetic layer 1 and the first electrode 11, and the cap layer 13 is located between the second ferromagnetic layer 2 and the second electrode 12. The insulating layer 16 is formed between the lens 20 and the cap layer 13 or the second electrode 12, and is provided so as to cover the periphery of the laminate 15 and the first electrode 11.

The magnetic element 10 is, for example, a MTJ (Magnetic Tunnel Junction) element in which the spacer layer 3 is made of an insulating material. In this case, the magnetic element 10 can exhibit a tunnel magnetoresistance (TMR) effect. The resistance value of the magnetic element 10 changes when the magnetic element 10 is irradiated with light from the outside. In the magnetic element 10, the resistance value in the z-axis direction (resistance value when a current flows in the z-axis direction) changes according to the relative change between the state of the magnetization M1 of the first ferromagnetic layer 1 and the state of the magnetization M2 of the second ferromagnetic layer 2. For example, the resistance value in the z-axis direction of the magnetic element 10 changes according to the change in the relative angle between the direction of the magnetization M1 of the first ferromagnetic layer 1 and the direction of the magnetization M2 of the second ferromagnetic layer 2. In addition, for example, the resistance value in the z-axis direction of the magnetic element 10 changes according to the change in the magnitude of the magnetization M1 of the first ferromagnetic layer 1.

In addition, for example, when the spacer layer 3 is made of metal, the magnetic element 10 can exhibit a giant magnetoresistance (GMR) effect. Such an element is called a GMR element. Even when the magnetic element 10 is a GMR element, the resistance value in the z-axis direction (resistance value when a current flows in the z-axis direction) changes according to the relative change between the state of magnetization M1 of the first ferromagnetic layer 1 and the state of magnetization M2 of the second ferromagnetic layer 2. The magnetic element 10 may be called an MTJ element, a GMR element, etc., depending on the material of the spacer layer 3, but is also collectively called a magnetoresistance effect element. The total thickness of the magnetic element 10 is, for example, 15 nm to 40 nm.

The magnetic element 10 may have a ferromagnetic material whose magnetization state changes when irradiated with light, and the resistance value may change with the change in the magnetization state. For example, the magnetic element 10 may be an anisotropic magnetoresistance (AMR) effect element, a colossal magnetoresistance (CMR) effect element, or the like, in addition to the above-mentioned MTJ element and GMR element.

The magnetic element 10 is disposed at the focal position of the light in the usable band focused by the main lens 21. It is preferable that the focal position of the light in the usable band overlaps, for example, with the first ferromagnetic layer 1. For example, when the visible light is used, the magnetic element 10 is disposed at the focal position of light in a specific wavelength range of 380 nm or more and less than 800 nm. Also, when the infrared light is used, the magnetic element 10 is disposed at the focal position of light in a specific wavelength range of 800 nm or more and 1 mm or less. For example, when the ultraviolet light is used, the magnetic element 10 is placed at the focal position of light in a specific wavelength range of 200 nm or more and less than 380 nm.

The first ferromagnetic layer 1 is a light detection layer whose magnetization state changes when light is irradiated from the outside. The first ferromagnetic layer 1 is also called a magnetization free layer. The magnetization free layer is a layer containing a magnetic material whose magnetization state changes when a specific external energy is applied thereto. The specific external energy is, for example, light irradiated from the outside, a current flowing in the z-axis direction of the magnetic element 10, an external magnetic field, etc. The magnetization M1 of the first ferromagnetic layer 1 changes state depending on the intensity of the irradiated light.

The first ferromagnetic layer 1 contains a ferromagnetic material. The first ferromagnetic layer 1 contains at least one of the magnetic elements such as Co, Fe, or Ni. The first ferromagnetic layer 1 may contain elements such as B, Mg, Hf, and Gd in addition to the magnetic elements described above. The first ferromagnetic layer 1 may be, for example, an alloy containing a magnetic element and a non-magnetic element. The first ferromagnetic layer 1 may be composed of multiple layers. The first ferromagnetic layer 1 may be, for example, a CoFeB alloy, a laminate in which a CoFeB alloy layer is sandwiched between Fe layers, or a laminate in which a CoFeB alloy layer is sandwiched between CoFe layers. In general, “ferromagnetic” includes “ferrimagnetic”. The first ferromagnetic layer 1 may exhibit ferrimagnetic properties. Alternatively, the first ferromagnetic layer 1 may exhibit ferromagnetic properties that are not ferrimagnetic. For example, a CoFeB alloy exhibits ferromagnetic properties that are not ferrimagnetic.

The first ferromagnetic layer 1 may be an in-plane magnetized film with an easy axis of magnetization in the in-plane direction (any direction in the xy plane) or a perpendicular magnetized film with an easy axis of magnetization in the direction perpendicular to the film plane (z-axis direction).

The thickness of the first ferromagnetic layer 1 is, for example, 1 nm to 5 nm. The thickness of the first ferromagnetic layer 1 is preferably, for example, 1 nm to 2 nm. When the first ferromagnetic layer 1 is a perpendicular magnetized film, if the thickness of the first ferromagnetic layer 1 is thin, the effect of perpendicular magnetic anisotropy applied from the layers above and below the first ferromagnetic layer 1 is strengthened, and the perpendicular magnetic anisotropy of the first ferromagnetic layer 1 is enhanced. In other words, if the perpendicular magnetic anisotropy of the first ferromagnetic layer 1 is high, the force that causes the magnetization M1 to return to the z-axis direction is strengthened. On the other hand, if the thickness of the first ferromagnetic layer 1 is large, the effect of applying perpendicular magnetic anisotropy from the layers above and below the first ferromagnetic layer 1 becomes relatively weak, and the perpendicular magnetic anisotropy of the first ferromagnetic layer 1 becomes weak.

If the thickness of the first ferromagnetic layer 1 becomes thin, the volume of the ferromagnetic body becomes small, and if the thickness becomes thick, the volume of the ferromagnetic body becomes large. The responsiveness of the magnetization of the first ferromagnetic layer 1 when external energy is applied is inversely proportional to the product (KuV) of the magnetic anisotropy (Ku) and the volume (V) of the first ferromagnetic layer 1. In other words, if the product of the magnetic anisotropy and the volume of the first ferromagnetic layer 1 becomes small, the responsiveness to light increases. From this perspective, in order to increase the responsiveness to light, it is preferable to appropriately design the magnetic anisotropy of the first ferromagnetic layer 1 and then reduce the volume of the first ferromagnetic layer 1.

If the thickness of the first ferromagnetic layer 1 is thicker than 2 nm, an insertion layer made of, for example, Mo or W may be provided in the first ferromagnetic layer 1. In other words, the first ferromagnetic layer 1 may be a laminate in which a ferromagnetic layer, an insertion layer, and a ferromagnetic layer are stacked in the z-axis direction. The perpendicular magnetic anisotropy of the entire first ferromagnetic layer 1 is enhanced by the interface magnetic anisotropy at the interface between the insertion layer and the ferromagnetic layer. The thickness of the insertion layer is, for example, 0.1 nm to 1.0 nm.

The second ferromagnetic layer 2 is a magnetization fixed layer. The magnetization fixed layer is a layer made of a magnetic material whose magnetization state is less likely to change when a specific external energy is applied than the magnetization free layer. For example, the magnetization direction of the magnetization fixed layer is less likely to change when a specific external energy is applied than the magnetization free layer. In addition, for example, the magnetization of the fixed layer is less likely to change when a certain external energy is applied than that of the free layer. The coercive force of the second ferromagnetic layer 2 is, for example, greater than that of the first ferromagnetic layer 1. The second ferromagnetic layer 2 has an easy magnetization axis in the same direction as that of the first ferromagnetic layer 1. The second ferromagnetic layer 2 may be an in-plane magnetized film or a perpendicular magnetized film.

The material constituting the second ferromagnetic layer 2 is, for example, the same as that of the first ferromagnetic layer 1. The second ferromagnetic layer 2 may be a multilayer film in which, for example, Co having a thickness of 0.4 nm to 1.0 nm and Pt having a thickness of 0.4 nm to 1.0 nm are alternately stacked several times. The second ferromagnetic layer 2 may be, for example, Co having a thickness of 0.4 nm to 1.0 nm, Mo having a thickness of 0.1 nm to 0.5 nm, and Pt having a thickness of 0.3 nm to 1. Alternatively, the spacer layer 3 may be a laminate in which a CoFeB alloy with a thickness of 0.0 nm and Fe with a thickness of 0.3 nm to 1.0 nm are laminated in this order.

The spacer layer 3 is a layer disposed between the first ferromagnetic layer 1 and the second ferromagnetic layer 2. The spacer layer 3 is composed of a layer composed of a conductor, an insulator, or a semiconductor, or a layer containing a current-carrying point composed of a conductor in an insulator. The spacer layer 3 is, for example, a non-magnetic layer. The thickness of the spacer layer 3 can be adjusted according to the orientation direction of the magnetization of the first ferromagnetic layer 1 and the magnetization of the second ferromagnetic layer 2 in the initial state described later.

When the spacer layer 3 is composed of an insulating material, a material containing aluminum oxide, magnesium oxide, titanium oxide, silicon oxide, or the like can be used as the material of the spacer layer 3. These insulating materials may also contain elements such as Al, B, Si, Mg, or magnetic elements such as Co, Fe, and Ni. By adjusting the thickness of the spacer layer 3 so that a high TMR effect occurs between the first ferromagnetic layer 1 and the second ferromagnetic layer 2, a high magnetoresistance change rate can be obtained. In order to efficiently utilize the TMR effect, the thickness of the spacer layer 3 may be about 0.5 nm to 5.0 nm, or about 1.0 nm to 2.5 nm.

When the spacer layer 3 is made of a nonmagnetic conductive material, conductive materials such as Cu, Ag, Au, or Ru can be used. In order to efficiently utilize the GMR effect, the thickness of the spacer layer 3 may be about 0.5 nm to 5.0 nm, or about 2.0 nm to 3.0 nm.

When the spacer layer 3 is made of a non-magnetic semiconductor material, materials such as zinc oxide, indium oxide, tin oxide, germanium oxide, gallium oxide, or indium tin oxide (ITO) can be used. In this case, the thickness of the spacer layer 3 may be about 1.0 nm to 4.0 nm.

When a layer including a current-carrying point formed by a conductor in a non-magnetic insulator is applied as the spacer layer 3, a structure including a current-carrying point formed by a non-magnetic conductor such as Cu, Au, or Al in a non-magnetic insulator made of aluminum oxide or magnesium oxide may be used. The conductor may also be made of magnetic elements such as Co, Fe, or Ni. In this case, the thickness of the spacer layer 3 may be about 1.0 nm to 2.5 nm. The current-carrying point is, for example, a columnar body with a diameter of 1 nm to 5 nm when viewed perpendicular to the film surface.

The cap layer 4 is provided between the first ferromagnetic layer 1 and the first electrode 11. The cap layer 4 may include a perpendicular magnetization induction layer (not shown) that is laminated on the first ferromagnetic layer 1 and in contact with the first ferromagnetic layer 1. The cap layer 4 prevents damage to the lower layer during the manufacturing process and enhances the crystallinity of the lower layer during annealing. The thickness of the cap layer 4 is, for example, 10 nm or less so that the first ferromagnetic layer 1 is irradiated with sufficient light.

The insulating layer 16 is provided between the lens 20 (main lens 21, sub lens 22) and the second electrode 12 or the cap layer 13, and is formed to cover the periphery of the magnetic element 10 and the first electrode 11. The insulating layer 16 is, for example, an oxide, nitride, or oxynitride of Si, Al, or Mg. The insulating layer 16 is, for example, silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide (ZᵣOₓ), etc. The insulating layer 16 transmits light in the used wavelength range. The insulating layer 16 preferably transmits, for example, 80% or more of light in the used wavelength range.

The first electrode 11 is, for example, disposed on the lens 20 side of the magnetic element 10. Incident light is irradiated to the magnetic element 10 from the first electrode 11 side, and is irradiated to at least the first ferromagnetic layer 1. The first electrode 11 is made of a material having electrical conductivity. The first electrode 11 is, for example, a transparent electrode that is transparent to light in the used wavelength range. The first electrode 11 preferably transmits, for example, 80% or more of light in the wavelength range used. The first electrode 11 is, for example, an oxide such as indium tin oxide (ITO), indium zinc oxide (IZO), zinc oxide (ZnO), or indium gallium zinc oxide (IGZO). The first electrode 11 may be configured to have multiple metal columns in a transparent electrode material of these oxides.

It is not essential to use the above-mentioned transparent electrode material for the first electrode 11. A thin metal material such as Au, Cu, or Al may be used to allow the irradiated light to reach the first ferromagnetic layer 1. When a metal is used as the material for the first electrode 11, the thickness of the first electrode 11 is, for example, 3 nm to 10 nm. The first electrode 11 may also have an anti-reflection film on the irradiation surface to which light is irradiated.

The second electrode 12 is made of a material having electrical conductivity. The second electrode 12 is made of a metal such as Cu, Al, or Au. Ta or Ti may be laminated above and below these metals. A laminated film of Cu and Ta, a laminated film of Ta, Cu, and Ti, or a laminated film of Ta, Cu, and TaN may also be used. TiN or TaN may also be used as the second electrode 12. The film thickness of the second electrode 12 is, for example, 200 nm to 800 nm.

The second electrode 12 may be transparent to the light irradiated to the magnetic element 10. Similarly to the first electrode 11, the second electrode 12 may be made of an oxide transparent electrode material such as indium tin oxide (ITO), indium zinc oxide (IZO), zinc oxide (ZnO), or indium gallium zinc oxide (IGZO). Even when light is irradiated from the first electrode 11, the light may reach the second electrode 12 depending on the intensity of the light. In this case, the second electrode 12 is made of an oxide transparent electrode material, so that the reflection of light at the interface between the second electrode 12 and the layer in contact with it can be suppressed compared to when the second electrode 12 is made of a metal.

As shown in FIG. 1, the light detection element 101 has a lens 20, i.e., a main lens 21 and a sub-lens 22, provided on the insulating layer 16. The sub-lens 22 includes four sub-lenses 22₁, 22₂, 22₃, and 22₄. The main lens 21 is circular in plan view from the z-axis direction, but may be rectangular, polygonal, etc. The sub-lens 22 is circular in plan view from the z-axis direction, but may be rectangular, polygonal, etc.

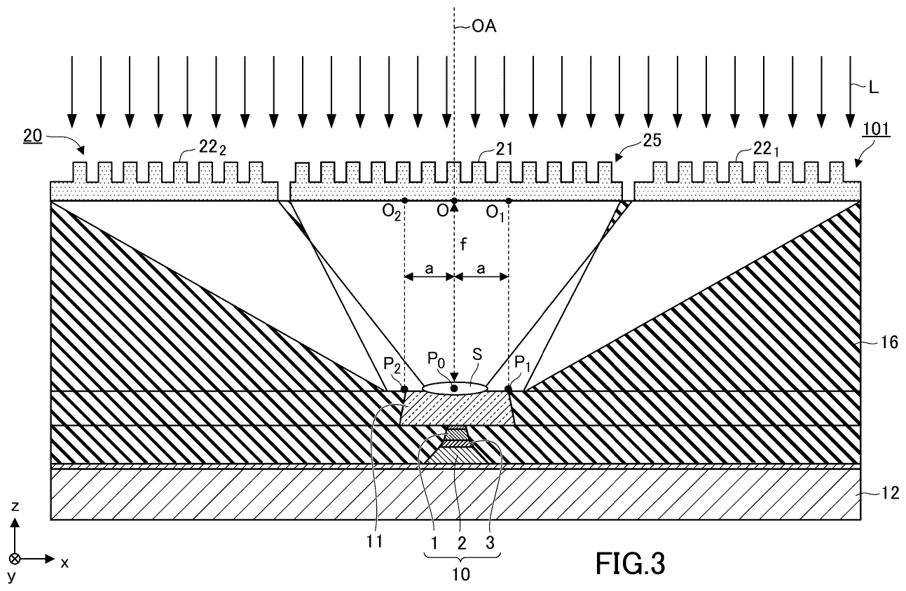

FIG. 3 is a diagram showing how the light L incident on the light detection element 101 shown in FIG. 1 is focused by the lens 20 and irradiated to the magnetic element 10 in the light detection element 101 shown in FIG. 1. Specifically, the light focused by the main lens 21 is irradiated to the magnetic element 10. The sub-lens 22 narrows the light spot formed by the main lens 21.

In detail, the incident light L on the main lens 21 is focused by the main lens 21 to form a light spot (also called “light spot before synthesis”) centered on a focal point P₀ at a focal length f. The incident light L on the sub-lens 22₁ is focused by the sub-lens 22₁ to form a light spot (also called “light spot before synthesis”) centered on a focal point P₁ at a focal length f. The incident light L on the sub-lens 22₂ is focused by the sub-lens 22₂ to form a light spot (also called “light spot before synthesis”) centered on a focal point P₂ at a focal length f. The focal point P₀ of the main lens 21, the focal point P₁ of the sub-lens 22₁, and the focal point P₂ of the sub-lens 22₂ are close to each other, and the light spot before synthesis formed by the main lens 21 partially overlaps with the light spots formed by the sub-lens 22₁ and the sub-lens 22₂, causing optical interference. The same is true for the sub-lenses 22₃, and 22₄.

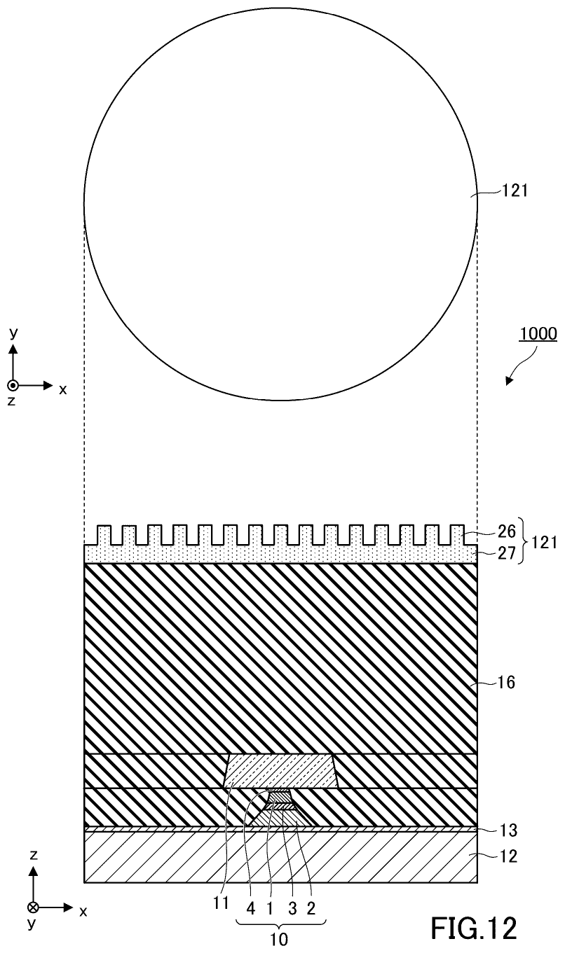

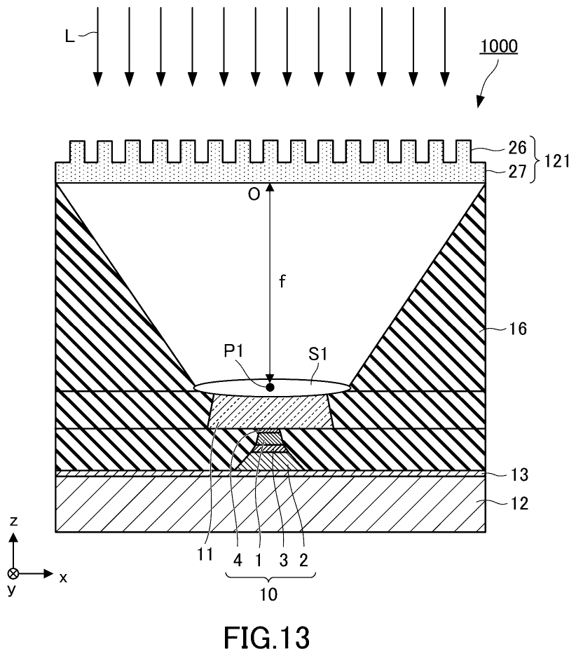

More specifically, the phase at the focal point P₀ of the main lens 21 is different from the phase at the focal points P₁, P₂, P₃, and P₄ of the sub-lenses 22₁, 22₂, 22₃, and 22₄, The focal point P₀ of the main lens 21 and the focal points P₁, P₂, P₃, and P₄ of the sub-lenses 22₁, 22₂, 22₃, and 22₄, are close to different points on the same plane. As a result, in the area where the light irradiated from the main lens 21 to the magnetic element 10 and the light irradiated from the sub-lens 22 to the magnetic element 10 overlap, the light irradiated from the sub-lens 22 cancels out part of the light irradiated from the main lens 21. As a result, when the light irradiated from the main lens 21 and the sub-lens 22 are combined or synthesized, the light spot S after synthesis becomes smaller than the light spot before synthesis. In this way, the light spot irradiated on the magnetic element 10 can be made small, and the heat energy generated by the light can be efficiently dissipated, so that the light detection element 101 can perform high-speed light detection. In contrast, the light detection element 1000 according to the related art, as shown in FIGS. 12 and 13, does not have a sub-lens as shown in the first embodiment of the present disclosure, so the light spot S1 formed by the lens 121 is not narrowed. Therefore, the light detection element 1000 according to the related art has a larger light spot S1 formed by the lens 121 than the first embodiment of the present disclosure, and the light detection speed by the light detection element 1000 is inferior.

In the first embodiment of the present disclosure, the number of sub-lenses 22 is four, but it may be one, two, or three, or it may be five or more. When multiple sub-lenses 22 are used, the effect of the sub-lenses to reduce the light spot can further be enhanced.

Multiple sub-lenses 22 may be provided, and their respective focal points P₁, P₂, P₃, and P₄ may surround the focal point P₀ of the main lens 21. This allows the overall size of the light spot S irradiated onto the magnetic element 10 to be reduced.

The focal point P₀ of the main lens 21 is preferably arranged so as to overlap with the magnetic element 10 when viewed from the direction of the optical axis OA of the main lens 21 (z-axis direction or surface perpendicular direction). This allows for strong light to be irradiated onto the magnetic element 10.

The focal point Pn (n is an integer between 1 and 4) of the sub-lens 22 is preferably arranged so as not to overlap with the magnetic element 10 when viewed from the optical axis direction (z-axis direction or surface perpendicular direction) of the sub-lens 22. This reduces the effect of light being cancelled out in the magnetic element 10, and allows for strong light to be irradiated onto the magnetic element 10.

The focal point Pn (n is an integer between 1 and 4) of the sub-lens 22 may be arranged in a pre-combination light spot formed on a plane perpendicular to the optical axis and passing through the focal point P₀ of the main lens 21, with the focal point P₀ as the center. This allows the composite light spot S, which is a combination of the light irradiated from the sub-lens 22 and the main lens 21, to be made smaller.

The main lens 21 and at least one sub-lens 22n (n is an integer between 1 and 4) of the sub-lenses 22 are preferably arranged on the same plane. By forming the main lens 21 and at least one sub-lens 22n of the sub-lenses 22 on the same plane, the manufacturing process becomes easier. In this embodiment, the main lens 21 and four sub-lenses 22 are arranged on the same plane.

The phase at the focal point P₀ of the main lens 21 and the phase at the focal point Pn (n is an integer between 1 and 4) of at least one of the sub-lenses 22n may be set to be 180 degrees different from each other. This allows the spot S of the composite light formed by combining the light irradiated from the main lens 21 and the sub-lens 22 to be smaller.

At least one of the sub-lenses 22n (n is an integer between 1 and 4) of the sub-lenses 22 may be configured to have a smaller area than the main lens 21 in a plan view seen from the optical axis direction (z-axis direction). This allows the effect of canceling the light of the sub-lens 22 to be weakened in the composite light formed by combining the light irradiated from the sub-lens 22 and the main lens 21, and therefore the light irradiated to the magnetic element 10 to be strengthened.

At least one of the sub-lenses 22n (n is an integer between 1 and 4) may have a larger area than the main lens 21 in a planar view from the optical axis direction (z-axis direction). This enhances the effect of the sub-lens 22 in the composite light formed by combining the light irradiated from the sub-lens 22 and the main lens 21, thereby allowing the light spot S irradiated onto the magnetic element 10 to be made smaller.

At least one of the main lens 21 and the sub-lens 22 may be a metalens 25 having a plurality of nanostructures 26 arranged two-dimensionally. This allows the main lens 21 and the sub-lens 22 to be molded in the same manufacturing process as the magnetic element 10, thereby making the manufacturing process easier. In this embodiment, the main lens 21 and the sub-lens 22 are metalens 25 each having a plurality of nanostructures 26 arranged two-dimensionally.

The metalens 25 is a lens that applies a metasurface. The metalens 25 functions as a lens by controlling the phase distribution of light. The metasurface exhibits the function of a metamaterial by its planar structure. A metamaterial is a medium with a negative refractive index, or a medium designed to have a refractive index (dielectric constant, magnetic permeability) that does not exist in nature. The metalens 25 can reduce the focal length, so the light detection element 101 can be made smaller.

The metalens 25 includes, for example, a dielectric material in which surface plasmon excitation occurs. The metalens 25 also transmits light in the band of use. The metalens 25 may be made of at least one material selected from the group consisting of, for example, tantalum oxide, silicon nitride, titanium oxide, gallium oxide, silicon oxide, and aluminum oxide. The film thickness of the metalens 25, i.e., the thickness in the z-axis direction, is, for example, 100 nm to 10 μm.

The metalens 25 can control the phase distribution of light by adjusting the arrangement of the nanostructures 26, the size of each nanostructure 26, and the period of arrangement of the nanostructures 26. In addition, by adjusting the size and period of arrangement of the nanostructures 26, it is possible to make the focal length of the metalens 25 the same even if the wavelength of the incident light is different.

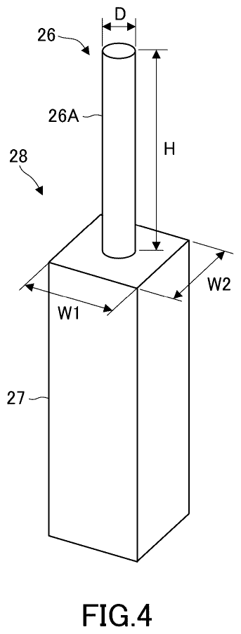

FIG. 4 is a perspective view showing the configuration of the unit structure 28 that constitutes the metalens 25. As shown in FIG. 4, the unit structure 28 constituting the metalens 25 includes a base portion 27 and a pillar 26A as a nanostructure 26. The base portion 27 is a rectangular parallelepiped, and its upper surface is a rectangle with a width W1 and a depth W2. The width W1 is, for example, 450 nm, and the depth W2 is, for example, 450 nm. The pillar 26A is formed on the upper surface of base portion 27, and is a cylinder with diameter D and height H. The diameter D of pillar 26A is, for example, 40 to 360 nm, and the height His, for example, 2 μm. The base portion 27 and the pillar 26A are composed of, for example, SiO₂.

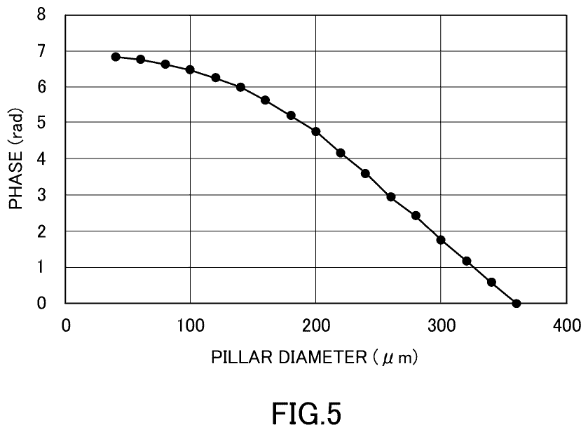

FIG. 5 is a graph showing the results of a simulation of the relationship between the diameter D of the pillar 26A and the phase of the light passing through the pillar 26A. The wavelength of the incident light was 520 nm. As shown in FIG. 5, the diameter D of the pillar 26A and the phase of the light correspond one-to-one, and as the diameter D of the pillar 26A increases, the phase of the light decreases. Therefore, by changing the diameter D of the pillar 26A, the phase of the light passing through the pillar 26A can be changed.

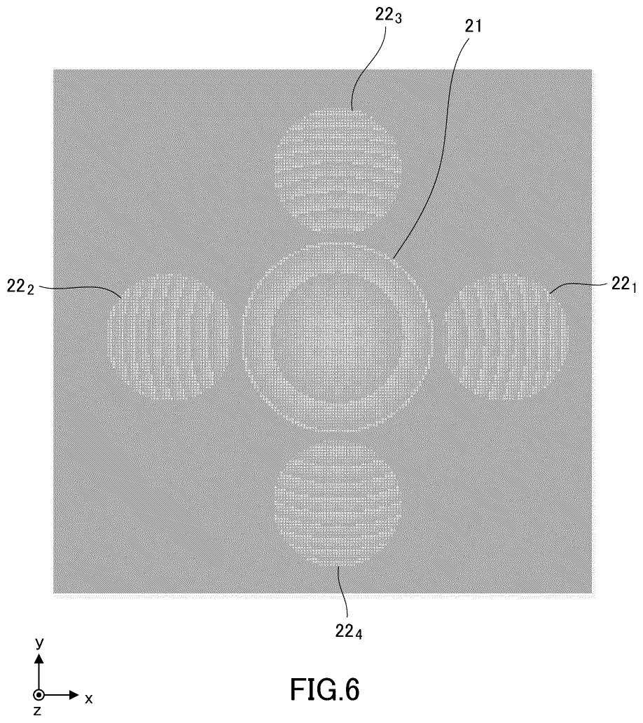

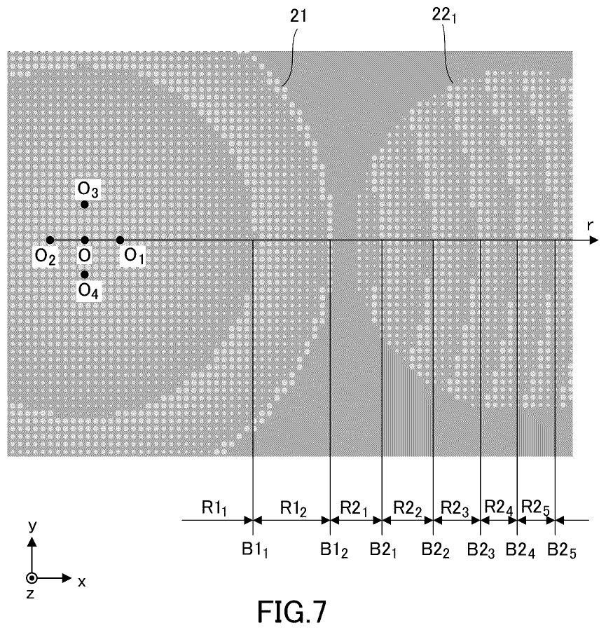

FIG. 6 is a plan view showing the results of simulating the configuration of the metalens 25 in FIG. 1, and FIG. 7 is a partially enlarged plan view thereof. As shown in FIGS. 6 and 7, the metalens 25 has a plurality of nanostructures 26 arranged two-dimensionally on the xy plane. The plurality of nanostructures 26 may be arranged in a predetermined arrangement pattern on the base portion 27 within the region R, such as a circle, a semicircle, a ring, or a partial ring. The nanostructure 26 in FIG. 6 is a cylindrical pillar 26A, but may be a prism, a rectangular parallelepiped, or the like.

When the nanostructure 26 is a cylindrical pillar 26A, the metalens 25 may include multiple types of nanostructures 26 with different diameters D of the circular upper surfaces and different cylindrical heights H. When the nanostructure 26 is a rectangular parallelepiped, the arrangement angle of the nanostructures 26 may vary depending on the positions within the region R. The arrangement angle is the angle that the longitudinal direction of the rectangular upper surface of the nanostructure 26 makes with respect to a reference axis (e.g., the x-axis direction). The distribution of the arrangement angle may have regularity, for example, according to the Pancharatnam Berry geometric degree. The size of the upper surface of the nanostructure 26 (diameter D of the circular upper surface in the case of a cylinder, the longitudinal length and width in the transverse direction of the upper surface rectangle in the case of a rectangular parallelepiped) and the interval between adjacent nanostructures 26 are equal to or less than the wavelength of the light used.

The area of each of the nanostructures 26 contained in the region R, such as a circle, a semicircle, an annulus, or a partial annulus, as viewed in a plan view from the z-axis direction may vary, for example, according to the distance from the center of the region R. The area of each of the nanostructures 26 contained in the region R, as viewed in a plan view from the z-axis direction, may decrease, for example, from the center of the region R to the outside. The center of the region R is the center of the circle or annulus, and is the center of a complete circle or annulus that partially includes the semicircle or partial annulus.

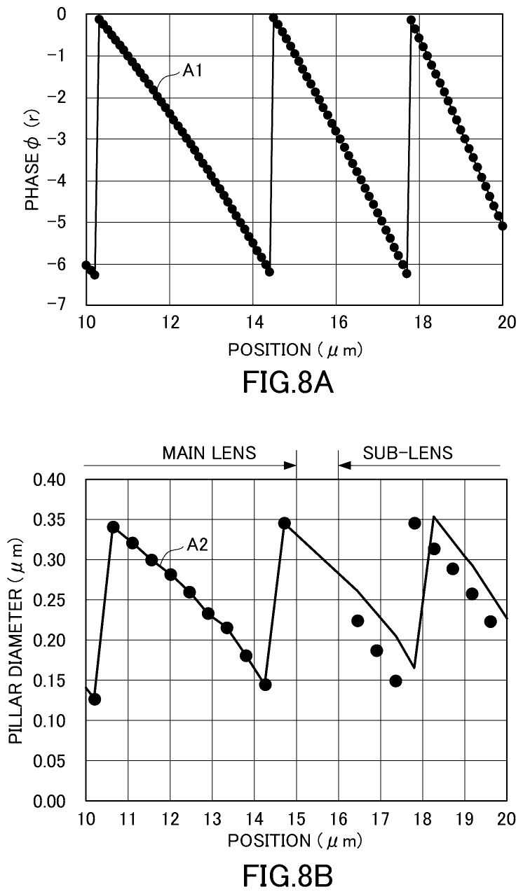

FIG. 8A is a graph showing the relationship A1 between the position of the pillar 26A in the metalens 25 of FIG. 1 and the phase of the light passing through the pillar 26A, and FIG. 8B is a graph showing the relationship A2 between the position of the pillar 26A and the pillar diameter D. As shown in FIG. 7 and FIG. 8A, the size (or diameter or area) of the pillars 26A as the multiple nanostructures 26 in the main lens 21 in plan view from the z-axis direction (optical axis direction) decreases as the distance from the optical center O of the main lens 21 increases in each region defined by the discontinuity points of the following equation (1) as boundaries.

$$ϕ ( r ) = - 2 π ( \frac{\sqrt{{f}^{2} + {r}^{2}} - f}{λ} - floor ( \frac{\sqrt{{f}^{2} + {r}^{2}} - f}{λ} ) ) \qquad ( 1 )$$

Furthermore, the size (or diameter or area) of the pillars 26A as the multiple nanostructures 26 in the sub-lens 22 in plan view from the z-axis direction decreases as the distance from the optical center Oₙ (n is an integer between 1 and 4) of the sub-lens 22 increases in each region defined by the discontinuity points of the following equation (2) as boundaries.

$$ϕ ( r ) = - 2 π ( \frac{\sqrt{{f}^{2} + {( r - a )}^{2}} - f}{λ} - floor ( \frac{\sqrt{{f}^{2} + {( r - a )}^{2}} - f}{λ} ) ) + Δ ϕ \qquad ( 2 )$$

In the above equations (1) and (2), r is the distance from the optical center O of the main lens 21 (i.e., the origin), f is the focal length of the main lens 21 and the sub-lens 22, λ is the wavelength of the incident light, φ is the phase of the light, a is the distance between the optical center O of the main lens 21 and the optical center Oₙ of the sub-lens 22 (n is an integer between 1 and 4), Δφ is the phase difference, and floor is a floor function that returns the maximum integer less than or equal to the argument. The optical center O of the main lens 21 is the principal point of the main lens 21, and is the intersection of the optical axis OA passing through the focal point P₀ of the main lens 21 and the principal surface of the main lens 21. The optical center Oₙ of the sub-lens 22 is the principal point of the sub-lens 22, and is the intersection of the optical axis passing through the focal point Pₙ of the sub-lens 22 and the principal surface of the sub-lens 22 (n is an integer between 1 and 4). The phase difference Δφ is, for example, π[rad]. The focal length f of the main lens 21 is the distance between the main lens 21 and the magnetic element 10, and is, for example, 100 μm. The focal length f of the sub-lens 22 is the distance between the sub-lens 22 and the magnetic element 10, and is, for example, 100 μm. The diameter of the main lens 21 is, for example, 30 μm, and the diameter of the sub-lens 22 is, for example, 20 μm.

The phase φ(r) in equation (1) decreases monotonically from 0 to −2π, and when it reaches −2π, it repeats the behavior of returning to 0. That is, φ(r) becomes a discontinuous point at r=B1₁, B1₂, . . . where φ(r)=−2π. In the main lens 21, the discontinuous points B1₁, B1₂, . . . are used as boundaries to determine the regions R1₁, R1₂, . . . between adjacent discontinuous points. However, region R1₁, R1₂ is a region within a circle centered on the optical center O and passing through discontinuity B1₁. Considering the relationship between the phase and the pillar diameter in FIG. 5, the pillar diameter at any position in each region can be determined.

In other words, the size (or diameter or area) of the multiple nanostructures 26 in the main lens 21 in plan view from the z-axis direction decreases as the distance from the optical center O of the main lens 21 increases in each region R1₁, R1₂, . . . defined by the discontinuity points B1₁, B1₂, . . . in equation (1).

The phase φ(r) in equation (2) monotonically decreases from Δφ to Δφ-2π, and when it reaches Δφ-2π, it repeats the behavior of returning to Δφ. For example, in the sub-lens 22₁, regions R2₁, R2₂, R2₃, R2₄, R2₅, . . . are defined between adjacent discontinuities with the discontinuities B2₁, B2₂, B2₃, B2₄, B2₅, . . . as boundaries. However, the region R2₁ is a region within a circle centered on the optical center O₁ and passing through the discontinuity B2₁.

That is, the size (or diameter or area) of the planar view of the multiple nanostructures 26 in the sub-lens 22₁ as viewed from the z-axis direction becomes smaller as the distance from the optical center O₁ of the sub-lens 22₁ increases in each region R2₁, R2₂, R2₃, R2₄, R2₅, . . . defined with the discontinuities B2₁, B2₂, B2₃, B2₄, B2₅, . . . of equation (2) as boundaries. The same applies to the other sub-lenses 22₂, 22₃, 22₄.

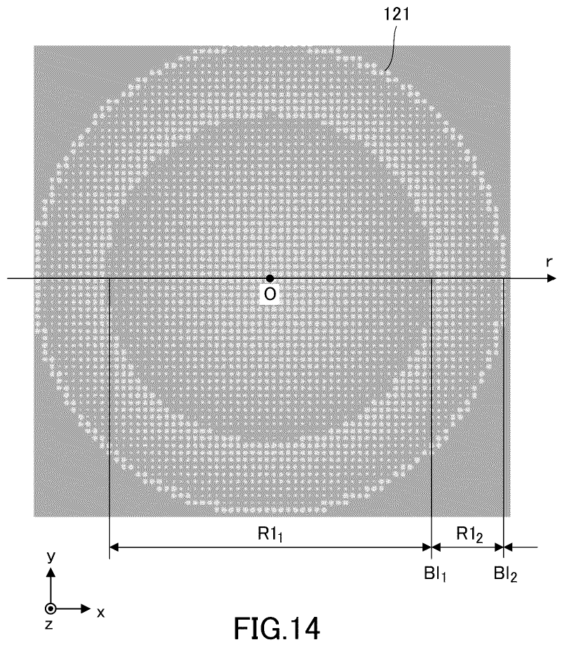

In contrast, in the light detection element 1000 according to the related art, as shown in FIG. 14, the configuration of the multiple nanostructures 26 in the lens 121 is the same as the configuration of the multiple nanostructures 26 in the main lens 21 of this embodiment. The lens 121 in FIG. 14 is, for example, a circle with a diameter of 30 μm. The nanostructure 26 is, for example, a pillar 26A. The focal length of the lens 121 is, for example, 100 μm. Therefore, the size (or diameter or area) of the multiple nanostructures 26 in the lens 121 in the plan view seen from the z-axis direction becomes smaller as the distance from the optical center O (coincident with the origin) of the lens 121 increases in each region R1₁, R1₂, . . . defined by the discontinuity points B1₁, B1₂, . . . of the above equation (1) as boundaries.

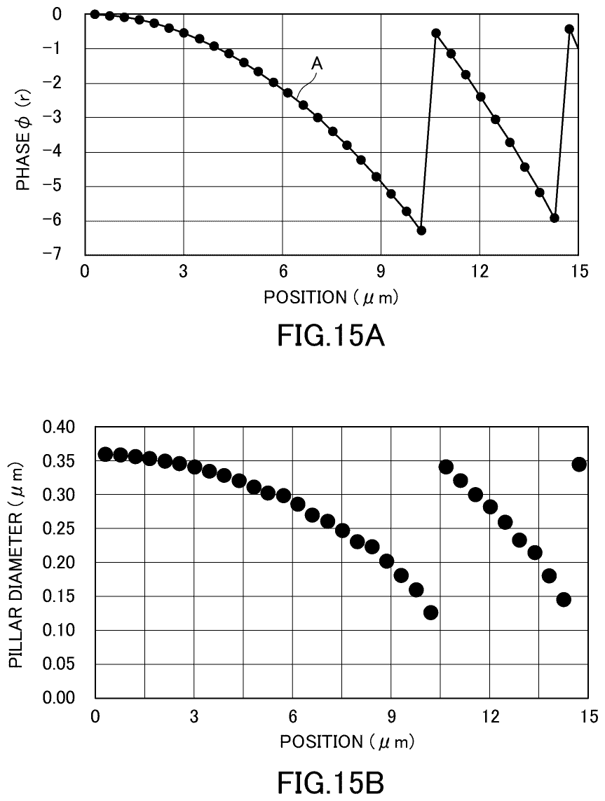

FIG. 15A is a graph showing the results of a simulation of the relationship A between the position of the pillar 26A in the lens 121 and the phase of the light passing through the pillar 26A for the light detection element 1000 according to the related art, and FIG. 15B is a graph showing the relationship between the position of the pillar 26A and the pillar diameter D. As can be seen from the above equation (1), the phase at each position can be calculated using the focal length f and the wavelength 2 of the light. Based on the relationship between the phase and the pillar diameter shown in FIG. 5, the lens 121 can be designed by converting the calculated phase into the diameter of the pillar 26A.

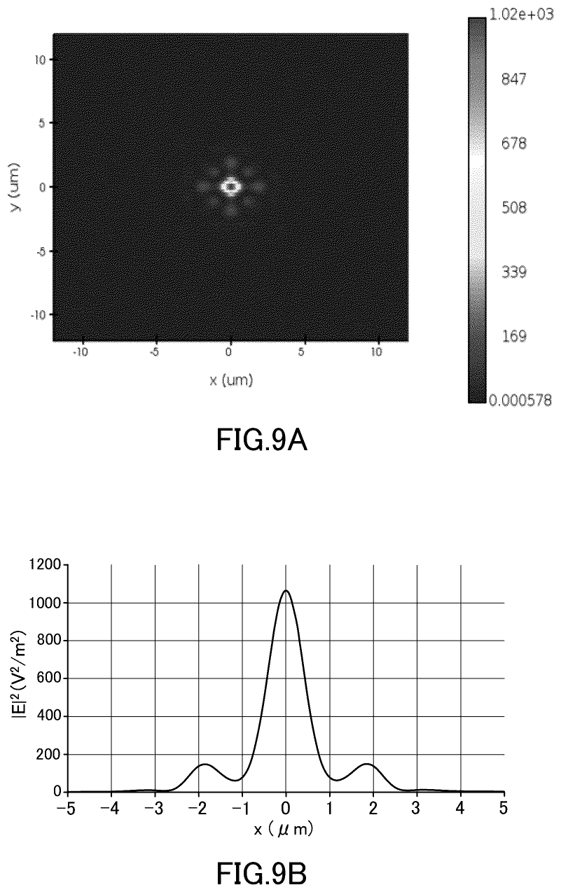

FIG. 9A is a plan view showing the simulation results of the light spot (intensity distribution) on the focal plane in the first embodiment of the present disclosure, and FIG. 9B is a graph showing the simulation results. From the simulation results in FIGS. 9A and 9B, the size of the light spot was 1.66 μm.

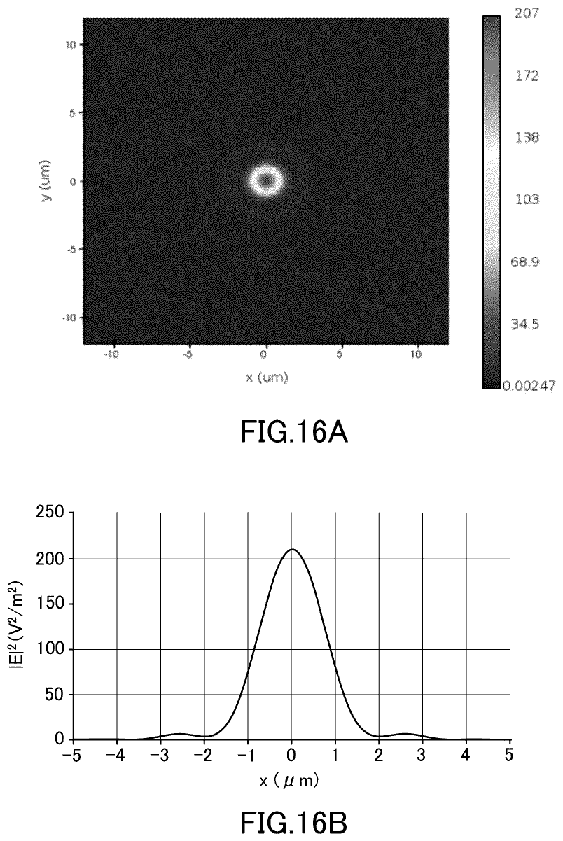

In contrast, in the light detection element 1000 according to the related art, the simulation results shown in FIGS. 16A and 16B show that the size of the light spot is 2.75 μm. Therefore, it was confirmed that the size of the light spot is reduced in this embodiment with a sub-lens compared to the light detection element 1000 according to the related art without a sub-lens.

In the first embodiment, the light incident on the main lens 21 may be light that has passed through a polarizing filter. The light detection element 101 may have a polarizing filter on the side of the main lens 21 opposite to the magnetic element 10. If the light incident on the light detection element 101 is polarized light such as laser light, the polarizing filter may not be required.

The light detection element 101 is obtained by sequentially fabricating the second electrode 12, the magnetic element 10, the first electrode 11, the insulating layer 16, and the lens 20 (main lens 21 and sub-lens 22).

The magnetic element 10 is fabricated by a process of stacking each layer, an annealing process, a processing process, etc. First, the cap layer 13, the second ferromagnetic layer 2, the spacer layer 3, the first ferromagnetic layer 1, and the cap layer 4 are stacked on the second electrode 12 in this order. Each layer is formed by, for example, sputtering.

Then, the laminated film is annealed. The annealing temperature is, for example, 250° C. to 400° C. Then, the laminated film is processed into a columnar laminate 15 by, for example, photolithography and etching. The laminate 15 may be in the shape of a mesa, a cylinder, a prism, a truncated cone, a truncated pyramid, or the like, either as a whole or in each layer. The shortest width of the laminate 15 when viewed from the z-axis direction is, for example, 10 nm to 1000 nm.

Then, an insulating layer 16 is formed so as to cover the side surface of the laminate 15. The insulating layer 16 may be laminated multiple times. Next, the upper surface of the cap layer 4 is exposed from the insulating layer 16 by, for example, chemical mechanical polishing, and a first electrode layer is formed on the cap layer 4 and the insulating layer 16 by sputtering. The first electrode layer is processed into a columnar or plate-shaped first electrode 11, for example, in a cylindrical shape, a prismatic shape, a truncated cone shape, a truncated pyramid shape, or the like, for example, by photolithography and etching. Next, an insulating layer 16 is embedded around the first electrode 11. Next, if necessary, the upper surface of the first electrode 11 is exposed from the insulating layer 16 by, for example, chemical mechanical polishing. Next, the insulating layer 16 is formed on the first electrode 11 and the insulating layer 16. The insulating layer 16 may be laminated multiple times.

Next, a lens 20 (main lens 21 and sub lens 22) is provided on the insulating layer 16. Specifically, a base portion 27 is formed on the upper surface of the insulating layer 16, a resist having a predetermined pattern formed by photolithography is formed on the upper surface of the base portion 27, and dry etching is performed. A plurality of nanostructures 26 having a predetermined pattern are formed on the upper surface of the base portion 27 by dry etching, thereby forming the metalens 25. The light detection element 101 is obtained by the above process. In this way, in the manufacture of the light detection element 101, the magnetic element 10 to the metalens 25 can be formed continuously by a vacuum film formation process.

Further, the main lens 21 and the sub-lens 22 are metalenses, but they may be, for example, microlenses. If the lens 20 is a metalenses, the main lens 21 and the sub-lens 22 can be integrally molded in the same process as the magnetic element 10, making the manufacturing process easier.

Next, the operation of the light detection element 101 according to the first embodiment will be described.

As shown in FIG. 3, the incident light L on the light detection element 101 is focused by the lens 20 and irradiated to the magnetic element 10, particularly the first ferromagnetic layer 1. When the intensity of the light irradiated to the first ferromagnetic layer 1 changes, the state of the magnetization M1 of the first ferromagnetic layer 1 changes. The state of magnetization M1 is, for example, the tilt angle of magnetization M1 with respect to the z-axis direction, the magnitude of magnetization M1, etc.

For example, when the intensity of light irradiated to the first ferromagnetic layer 1 increases, the magnetization M1 of the first ferromagnetic layer 1 tilts from its initial state due to the external energy caused by the light irradiation. The angle between the direction of magnetization M1 of the first ferromagnetic layer 1 when light is not irradiated to the first ferromagnetic layer 1 and the direction of magnetization M1 when light is irradiated is, for example, greater than 0° and smaller than 90°. Alternatively, for example, when the intensity of light irradiated to the first ferromagnetic layer 1 increases, the magnitude of magnetization M1 decreases.

When the state of magnetization M1 of the first ferromagnetic layer 1 changes, the resistance value of the magnetic element 10 in the z-axis direction changes due to the magnetoresistance effect. When a constant current (sense current) is passed in the positive or negative direction of the z-axis of the magnetic element 10 using the first electrode 11 and the second electrode 12, an output voltage is obtained from the magnetic element 10. That is, when the state of the magnetization M1 of the first ferromagnetic layer 1 changes, the output voltage from the magnetic element 10 also changes.

The intensity of the light irradiated to the first ferromagnetic layer 1 may take two values, for example, a first intensity and a second intensity. The first intensity may be the case where the intensity of the light irradiated to the first ferromagnetic layer 1 is zero. The intensity of the light irradiated to the first ferromagnetic layer 1 may take multiple values or may change analogically. When the intensity of the incident light takes multiple values, the output voltage of the magnetic element 10 also takes multiple values, and when the intensity of the light changes analogically, the output voltage of the magnetic element 10 can also change analogically. The difference between these output voltages (resistance values) can be read from the light detection element 101 as binary, multi-value, or analog data.

In a state where the first ferromagnetic layer 1 is irradiated with light of a first intensity (referred to as the “initial state”), the magnetization M1 of the first ferromagnetic layer 1 and the magnetization M2 of the second ferromagnetic layer 2 may be parallel or anti-parallel, or the magnetization M1 and the magnetization M2 may be perpendicular to each other.

When the magnetization M1 and the magnetization M2 are parallel in the initial state, a sense current is passed from the first ferromagnetic layer 1 to the second ferromagnetic layer 2. By passing the sense current in this direction, a spin transfer torque in the same direction as the magnetization M2 of the second ferromagnetic layer 2 acts on the magnetization M1 of the first ferromagnetic layer 1, and the magnetization M1 and the magnetization M2 become parallel in the initial state. In addition, by passing the sense current in this direction, it is possible to prevent the magnetization M1 of the first ferromagnetic layer 1 from being reversed during operation.

When the magnetization M1 and the magnetization M2 are antiparallel in the initial state, it is preferable to pass the sense current from the second ferromagnetic layer 2 to the first ferromagnetic layer 1. By passing the sense current in this direction, a spin transfer torque in the opposite direction to the magnetization M2 of the second ferromagnetic layer 2 acts on the magnetization M1 of the first ferromagnetic layer 1, and the magnetization M1 and the magnetization M2 become antiparallel in the initial state.

When the intensity of the light irradiated to the first ferromagnetic layer 1 returns to the first intensity, the spin transfer torque acts due to the sense current, or the state of the magnetization M1 of the first ferromagnetic layer 1 returns to its original state due to the effect of magnetic anisotropy, and the magnetic element 10 returns to its initial state.

In this way, the light detection element 101 according to the first embodiment can convert the change in the intensity of the irradiated light into a change in the output voltage from the magnetic element 10. That is, the light detection element 101 can convert light into an electrical signal.

As described above, in the first embodiment of the present disclosure, in order to reduce the spot of light irradiated on the magnetic element 10, a sub-lens 22 that narrows the light spot is provided in addition to the main lens 21. Specifically, the sub-lens 22 has focal points P₁, P₂, P₃, and P₄ at positions different from the focal point P₀ of the main lens 21 that irradiates light on the magnetic element 10 on the same plane (focal plane), and the phases at the focal points P₁, P₂, P₃, and P₄ are different from the phase at the focal point P₀ of the main lens 21. As a result, in the area where the light irradiated from the main lens 21 to the magnetic element 10 and the light irradiated from the sub-lens 22 to the magnetic element 10 overlap, the light irradiated from the sub-lens 22 cancels out a part of the light irradiated from the main lens 21. As a result, when the light irradiated from the main lens 21 and the sub-lens 22 are combined or synthesized, the light spot S after synthesis is smaller than the light spot before synthesis. In this way, the light spot irradiated to the magnetic element 10 can be made smaller, and the heat energy generated by the light can be efficiently dissipated, so that the light detection element 101 can perform high-speed light detection.

Next, a second embodiment of the present disclosure will be described. In the second embodiment, the lens configuration is different from that of the first embodiment. The other configurations are the same as those in the first embodiment, and the same components are given the same reference numerals and their explanations will be omitted as appropriate.

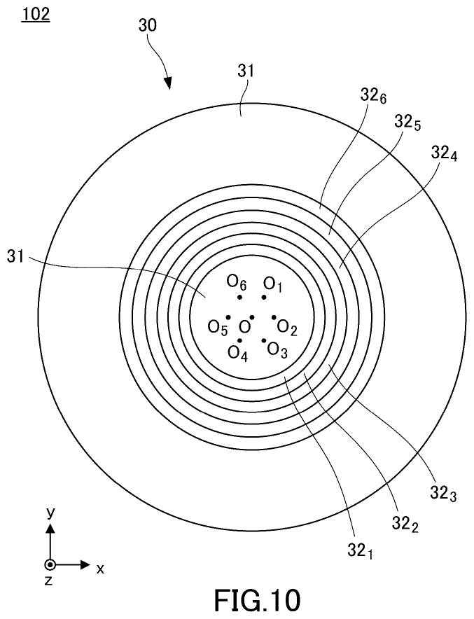

FIG. 10 is a plan view showing the configuration of the lens 30 of the light detection element 102 according to the second embodiment of the present disclosure. As shown in FIG. 10, in the light detection element 102, a part of the main lens 31 includes sub-lenses 32₁, 32₂, 32₃, 32₄, 32₅, and 32₆. Specifically, the main lens 31 is disc-shaped and has annular sub-lenses 32₁, 32₂, 32₃, 32₄, 32₅, and 32₆ of different sizes built into it.

The sub-lenses 32₁, 32₂, 32₃, 32₄, 32₅, and 32₆ have focal points at different positions and with different phases from the focal point of the main lens 31 on the focal plane of the main lens 31. Preferably, the phase at the focal point of the main lens 31 and the phase at the focal points of the sub-lenses 32₁, 32₂, 32₃, 32₄, 32₅, and 32₆ are different by, for example, 180°. Preferably, the focal points of the sub-lenses 32₁, 32₂, 32₃, 32₄, 32₅, and 32₆ surround the focal point of the main lens 31 on the focal plane. In this case, as shown in FIG. 10, the optical centers of the sub-lenses 32₁, 32₂, 32₃, 32₄, 32₅, and 32₆ are O₁, O₂, O₃, O₄, O₅, and O₆, respectively, and surround the origin O, which is the optical center of the main lens 31.

As a result, the light irradiated from the sub-lenses 32₁, 32₂, 32₃, 32₄, 32₅, and 32₆ cancels out a portion of the light irradiated from the main lens 31, and the spot of the composite light formed by combining the light irradiated from the main lens 31 and the sub-lenses 32₁, 32₂, 32₃, 32₄, 32₅, and 32₆ is smaller than the light spot formed by the main lens 31 alone. In other words, the spot of the light irradiated on the magnetic element 10 can be made smaller. This allows the light detection element 102 to perform high-speed light detection.

In addition, by including the sub-lenses 32₁, 32₂, 32₃, 32₄, 32₅, and 32₆ as part of the main lens 31, the process of forming the main lens 31 and the sub-lenses 32₁, 32₂, 32₃, 32₄, 32₅, and 32₆ can be made easier than when they are formed separately.

The third embodiment of the present disclosure will be described. The lens configuration of the third embodiment is different from that of the first and second embodiments. The other configurations are the same as those of the first and second embodiments, and the same components are given the same reference numerals and the description will be omitted as appropriate.

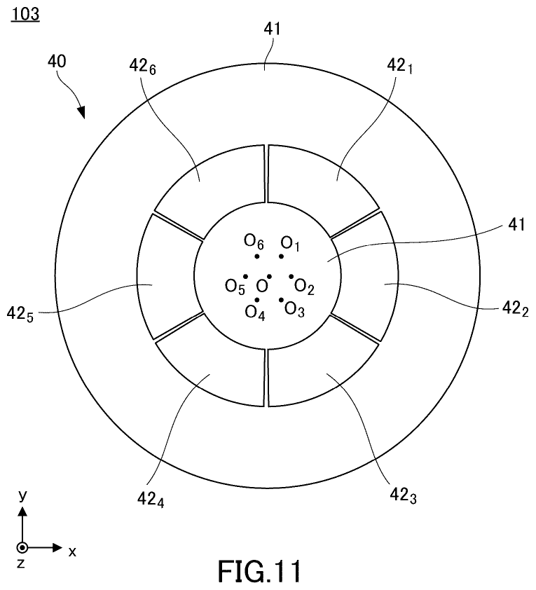

FIG. 11 is a plan view showing the configuration of the lens 40 of the light detection element 103 according to the third embodiment of the present disclosure. As shown in FIG. 11, in the light detection element 103, sub-lenses 42₁, 42₂, 42₃, 42₄, 42₅, and 42₆ are included in a part of the main lens 41. Specifically, the sub-lenses 42₁, 42₂, 42₃, 42₄, 42₅, and 42₆, which are parts of a ring, are incorporated into the disk-shaped main lens 41.

The sub-lenses 42₁, 42₂, 42₃, 42₄, 42₅, and 42₆ have foci at positions and phases different from the focal point of the main lens 41 on the focal plane of the main lens 41. Preferably, the phase at the focal point of the main lens 41 and the phase at the focal points of the sub-lenses 42₁, 42₂, 42₃, 42₄, 42₅, and 42₆ differ by, for example, 180°. The foci of the sub-lenses 42₁, 42₂, 42₃, 42₄, 42₅, and 42₆ preferably surround the focal point of the main lens 41 on the focal plane. In this case, as shown in FIG. 11, the optical centers of the sub-lenses 42₁, 42₂, 42₃, 42₄, 42₅, and 42₆ are O₁, O₂, O₃, O₄, O₅, and O₆, respectively, and surround the origin O, which is the optical center of the main lens 41.

As a result, the light irradiated from the sub-lenses 42₁, 42₂, 42₃, 42₄, 42₅, and 42₆ cancels out part of the light irradiated from the main lens 41, and the spot of the composite light, which is the combination of the light irradiated from the main lens 41 and the sub-lenses 42₁, 42₂, 42₃, 42₄, 42₅, and 42₆, becomes smaller than the light spot formed by the main lens 41 alone. In other words, the spot of the light irradiated on the magnetic element 10 can be made smaller. This allows the light detection element 103 to perform high-speed light detection.

Also, by including the sub-lenses 42₁, 42₂, 42₃, 42₄, 42₅, and 42₆ as part of the main lens 41, the process of forming the main lens 41 and the sub-lenses 42₁, 42₂, 42₃, 42₄, 42₅, and 42₆ can be made easier than when they are formed separately.

The light detection elements 101 to 103 of the first to third embodiments can be applied to, for example, optical sensors such as image sensors in which a plurality of light detection elements are arranged one-dimensionally or two-dimensionally. Such optical sensors can be used in information terminal devices such as smartphones, tablets, personal computers, and digital cameras.

Also, the light detection elements 101 to 103 of the first to third embodiments can be applied to, for example, photoelectric conversion elements of a receiver device provided in a transceiver device that transmits and receives optical signals such as laser light in a communication system in which a plurality of transceiver devices are connected by optical fibers. The above communication system may be, for example, a communication system for short- or medium-distance communication within a data center or between data centers, or long-distance communication between cities. The transceiver device is installed, for example, in a data center.

The above communication system may also be, for example, a communication system for wirelessly transmitting and receiving optical signals, such as near-infrared light signal, between mobile terminals, such as smartphones and tablets. The above communication system may also be, for example, a communication system for wirelessly transmitting and receiving optical signals, such as near-infrared light signal, between a mobile terminal and an information processing device, such as a personal computer.

The present disclosure is not limited to the above embodiments, and various modifications and alterations are possible within the scope of the gist of the present disclosure described in the claims.

As described above, the present disclosure has the effect of efficiently dissipating heat energy generated by light by concentrating the irradiated light in a narrow area and reducing the spot of light irradiated to the light detection element, thereby enabling high-speed light detection, and is useful for light detection elements in general.

### APPENDIX

One aspect of the present disclosure provides the light detection element that comprises a magnetic element including a first ferromagnetic layer, a second ferromagnetic layer, and a spacer layer sandwiched between the first ferromagnetic layer and the second ferromagnetic layer, a main lens including a metalens having a plurality of nanostructures arranged two-dimensionally, which irradiates incident light onto the magnetic element, and at least one sub-lens including a metalens having a plurality of nanostructures arranged two-dimensionally, which focuses the incident light to the magnetic element, wherein the size of the plurality of nanostructures in the main lens as viewed in a plan view from the optical axis direction of the main lens decreases as the distance from the optical center of the main lens increases in each region defined by the discontinuity points of equation (1) as boundaries, and the size of the plurality of nanostructures in the sub-lens as viewed in a plan view from the optical axis direction of the sub-lens decreases as the distance from the optical center of the sub-lens increases in each region defined by the discontinuity points of equation (2) as boundaries.

$$ϕ ( r ) = - 2 π ( \frac{\sqrt{{f}^{2} + {r}^{2}} - f}{λ} - floor ( \frac{\sqrt{{f}^{2} + {r}^{2}} - f}{λ} ) ) \qquad ( 1 )$$

$$ϕ ( r ) = - 2 π ( \frac{\sqrt{{f}^{2} + {( r - a )}^{2}} - f}{λ} - floor ( \frac{\sqrt{{f}^{2} + {( r - a )}^{2}} - f}{λ} ) ) + Δ ϕ \qquad ( 2 )$$

(In the above equations (1) and (2), r is the distance from the optical center of the main lens, f is the focal length of the main lens and the sub-lens, λ is the wavelength of the incident light, φ is the phase, a is the distance between the optical center of the main lens and the optical center of the sub-lens, Δφ is the phase difference, and floor is the floor function.)

With this configuration, the light detection element of the present disclosure has a phase difference between the focal point of the main lens and the focal point of the sub-lens. The focal points of the main lens and the sub-lens are separated by a distance a on the same plane (focal plane). As a result, the light irradiated from the sub-lens cancels out a portion of the light irradiated from the main lens, and the spot of light formed by the combination of the light irradiated from the main lens and the sub-lens becomes smaller. In other words, the spot of light irradiated to the magnetic element can be made smaller. This allows the magnetic element to perform high-speed light detection. Furthermore, since the main lens and the sub-lens are metalenses, they can be integrally molded in the same manufacturing process as the magnetic element, thereby making the manufacturing process easier.

One aspect of the present disclosure provides the light detection element, wherein the at least one sub-lens may comprise multiple sub-lenses.

With this configuration, the light detection element of the present disclosure can enhance the effect of narrowing the light spot by the sub-lenses by having multiple sub-lenses.

One aspect of the present disclosure provides the light detection element, wherein the at least one sub-lens may comprise multiple sub-lenses, and the focal points of the multiple sub-lenses may be arranged to surround the focal point of the main lens.

With this configuration, the light detection element of the present disclosure can reduce the overall size of the light spot irradiated on the magnetic element by arranging the focal points of the multiple sub-lenses to surround the focal point of the main lens.

One aspect of the present disclosure provides the light detection element, wherein the focal point of the main lens may be arranged to overlap the magnetic element when viewed from the optical axis direction of the main lens.

With this configuration, the light detection element of the present disclosure is able to irradiate the magnetic element with strong light by arranging the focal point of the main lens to overlap the magnetic element when viewed from the optical axis direction of the main lens.

One aspect of the present disclosure provides the light detection element, wherein the focal point of the sub-lens may be arranged so as not to overlap the magnetic element when viewed from the optical axis direction of the sub-lens.

With this configuration, the light detection element of the present disclosure is able to irradiate the magnetic element with strong light by arranging the focal point of the sub-lens to not overlap the magnetic element when viewed from the optical axis direction of the sub-lens, thereby reducing the effect of light cancellation in the magnetic element.

One aspect of the present disclosure provides the light detection element, wherein the focal point of the sub-lens may be located within a light spot formed on a plane where the focal point of the main lens exists and perpendicular to the optical axis direction of the main lens.

With this configuration, the light detection element of the present disclosure can make the spot of composite light formed by combining the light irradiated from the sub-lens and the main lens smaller by arranging the focal point of the sub-lens within a light spot formed on a plane (focal plane) where the focal point of the main lens exists and perpendicular to the optical axis direction of the main lens.

One aspect of the present disclosure provides the light detection element, wherein the main lens and the at least one sub-lens may be located on the same plane.

With this configuration, the light detection element of the present disclosure can make the manufacturing process easier by forming the main lens and at least one of the sub-lenses on the same plane.

One aspect of the present disclosure provides the light detection element, wherein the main lens and the at least one sub-lens may be configured such that the phases at their respective focal points differ by 180 degrees.

With this configuration, the light detection element according to the present disclosure can further reduce the spot of composite light formed by combining the light irradiated from the main lens and the sub-lens by having the phases at their respective focal points differ by 180 degrees.

One aspect of the present disclosure provides the light detection element, wherein the at least one sub-lens may be configured to have a smaller area than the main lens in a plan view seen from the optical axis direction of the sub-lens.

With this configuration, in the light detection element of the present disclosure, at least one of the sub-lenses has a smaller area in plan view from the optical axis direction than the main lens, so that in the composite light formed by combining the light irradiated from the sub-lens and the main lens, the effect of canceling the light of the sub-lens can be weakened, and the light irradiated to the magnetic element can be strengthened.

One aspect of the present disclosure provides the light detection element, wherein the at least one sub-lens may have a larger area in plan view from the optical axis direction than the main lens.

With this configuration, in the light detection element of the present disclosure, at least one of the sub-lenses has a larger area in a plan view from the optical axis direction than the main lens, and in the composite light that combines the light irradiated from the sub-lens and the main lens, the effect of the sub-lens is enhanced, and the spot of light irradiated on the magnetic element can be made smaller.

One aspect of the present disclosure provides the light detection element, wherein the at least one sub-lens may be included as part of the main lens.

With this configuration, in the light detection element of the present disclosure, at least one of the sub-lenses is included as part of the main lens, and the formation process of the main lens and the sub-lens can be made easier.

Although the disclosure has been described with respect to only a limited number of embodiments, those skilled in the art, having benefit of this disclosure, will appreciate that various other embodiments may be devised without departing from the spirit and scope of the present disclosure. Accordingly, the technical scope of the disclosed subject matter should be limited only by the attached claims.

### DESCRIPTION OF REFERENCE NUMERALS AND SIGNS

1 First ferromagnetic layer
2 Second ferromagnetic layer
3 Spacer layer
4, 13 Cap layer
10 Magnetic element
11 First electrode
12 Second electrode
15 Laminate
16 Insulating layer
20, 30, 40, 121 Lens
21, 31, 41 Main lens
22₁, 22₂, 22₃, 22₄ Sub-lens
25 Metalens
26 Nanostructure
26A Pillar
27 Base portion
28 Unit Structure
32₁, 32₂, 32₃, 32₄, 32₅, 32₆ Sub-lenses
42₁, 42₂, 42₃, 42₄, 42₅, 42₆ Sub-lenses
101, 102, 103, 1000 Light detection element
M1, M2 Magnetization
OA Optical axis
O Optical center (origin)
01, O₂, O₃, O₄, O₅, O₆ Optical center
P₀, P₁, P₂, P₃, P₄ Focal point
S, S1 Light spot

What is claimed is:

1. A light detection element comprising:
a magnetic element including a first ferromagnetic layer, a second ferromagnetic layer, and a spacer layer sandwiched between the first ferromagnetic layer and the second ferromagnetic layer;
a main lens including a metalens having a plurality of nanostructures arranged two-dimensionally, which irradiates incident light onto the magnetic element; and
at least one sub-lens including a metalens having a plurality of nanostructures arranged two-dimensionally, which focuses the incident light to the magnetic element;
wherein the size of the plurality of nanostructures in the main lens in plan view as viewed from the optical axis direction of the main lens decreases as the distance from the optical center of the main lens increases in each region defined by the discontinuity points of equation (1) as boundaries, and the size of the plurality of nanostructures in the sub-lens in plan view as viewed from the optical axis direction of the sub-lens decreases as the distance from the optical center of the sub-lens increases in each region defined by the discontinuity points of equation (2) as boundaries.
$$ϕ ( r ) = - 2 π ( \frac{\sqrt{{f}^{2} + {r}^{2}} - f}{λ} - floor ( \frac{\sqrt{{f}^{2} + {r}^{2}} - f}{λ} ) ) \qquad ( 1 )$$
$$ϕ ( r ) = - 2 π ( \frac{\sqrt{{f}^{2} + {( r - a )}^{2}} - f}{λ} - floor ( \frac{\sqrt{{f}^{2} + {( r - a )}^{2}} - f}{λ} ) ) + Δ ϕ . \qquad ( 2 )$$
(In the above equations (1) and (2), r is the distance from the optical center of the main lens, f is the focal length of the main lens and the sub-lens, λ is the wavelength of the incident light, φ is the phase, a is the distance between the optical center of the main lens and the optical center of the sub-lens, Δφ is the phase difference, and floor is the floor function.)

2. The light detection element according to claim 1, wherein the at least one sub-lens comprises a plurality of sub-lenses.

3. The light detection element according to claim 1, wherein the at least one sub-lens comprises a plurality of sub-lenses, and the focal points of the plurality of sub-lenses are arranged to surround the focal point of the main lens.

4. The light detection element according to claim 1, wherein the focal point of the main lens is arranged to overlap the magnetic element when viewed from the optical axis direction of the main lens.

5. The light detection element according to claim 1, wherein the focal point of the sub-lens is arranged so as not to overlap the magnetic element when viewed from the optical axis direction of the sub-lens.

6. The light detection element according to claim 1, wherein the focal point of the sub-lens is arranged within a light spot formed on a plane where the focal point of the main lens exists and perpendicular to the optical axis direction of the main lens.

7. The light detection element according to claim 1, wherein the main lens and the at least one sub-lens are arranged on the same plane.

8. The light detection element according to claim 2, wherein the phase at the focal point of the main lens and the phase at the focal point of each of the sub-lenses are different from each other.

9. The light detection element according to claim 1, wherein the phase at the focal point of the main lens and the phase at the focal point of the at least one sub-lens differ by 180 degrees.

10. The light detection element according to claim 1, wherein the at least one sub-lens has an area smaller than that of the main lens in a plan view viewed from the optical axis direction of the sub-lens.

11. The light detection element according to claim 1, wherein the at least one sub-lens has a larger area than the main lens in a plan view from the optical axis direction of the sub-lens.

12. The light detection element according to claim 1, wherein the at least one sub-lens is included as part of the main lens.

13. The light detection element according to claim 1, wherein the at least one sub-lens comprises four sub-lenses.

14. The light detection element according to claim 1, wherein the main lens and the at least one sub-lens are each made of at least one material selected from the group consisting of tantalum oxide, silicon nitride, titanium oxide, gallium oxide, silicon oxide, and aluminum oxide.

15. The light detection element according to claim 1, wherein the plurality of nanostructures are cylindrical pillars.

16. The light detection element according to claim 15, wherein the plurality of nanostructures include multiple types of structures having different diameters of their circular upper surfaces or different cylindrical heights.

17. The light detection element according to claim 1, wherein the plurality of nanostructures are rectangular-parallelepiped structures, and an angle formed between a longitudinal direction of the rectangular upper surface of the rectangular-parallelepiped structures and a reference direction varies depending on positions on the main lens and the at least one sub-lens.

18. The light detection element according to claim 1, further comprising an insulating layer that embeds a periphery of a laminate including the second ferromagnetic layer, the spacer layer, and the first ferromagnetic layer, wherein the insulating layer is an oxide, a nitride, or an oxynitride of Si, Al, or Mg.

19. A communication system comprising a plurality of transceiver devices that transmit and receive optical signals, each of the transceiver devices including a receiver device having the light detection element according to claim 1.

20. The communication system according to claim 19, wherein the optical signal is a near-infrared light signal.
